(19) United States
(12) Patent Application Publication
(10) Pub. No.: US 2023/0420371 A1
(43) Pub. Date: Dec. 28, 2023

(54) STACKED FIELD EFFECT TRANSISTOR CELL WITH CROSS-COUPLING

(71) Applicant: INTERNATIONAL BUSINESS MACHINES CORPORATION, ARMONK, NY (US)

(72) Inventors: Carl Radens, LaGrangeville, NY (US); Ruilong Xie, Niskayuna, NY (US); Albert M. Chu, Nashua, NH (US); Brent A. Anderson, Jericho, VT (US)

(21) Appl. No.: 17/809,076

(22) Filed: Jun. 27, 2022

(51) Int. Cl. H01L 23/535; H01L 23/528; H01L 27/11

(52) U.S. Cl. CPC H01L 23/535; H01L 23/5286; H01L 27/1104

(57) ABSTRACT

Embodiments are disclosed for a complementary metal oxide semiconductor (CMOS) device. The CMOS device includes a hybrid cross-couple contact. The hybrid cross-couple contact includes a frontside contact to a gate of the CMOS device. The frontside contact is disposed on a frontside of the CMOS device. The hybrid cross-couple contact includes a source contact to a source of the CMOS device. The source contact is disposed on a backside of the CMOS device. The hybrid cross-couple contact includes a drain contact to a drain of the CMOS device. The drain contact is disposed on a backside of the CMOS device.

### BACKGROUND

The present disclosure relates to a stacked field effect transistor (FET), and more specifically, to a stacked FET with cross-coupling.

Integrated circuits, such as microprocessors, may have a relatively large number of circuit elements, such as transistors, which are disposed in a limited chip area. The transistors can be n-type metal-oxide semiconductor field-effect transistors (nFET) or p-type metal-oxide semiconductor FET (pFET) type devices wherein the “N” and “P” designation depends on the type of dopants used in creating the source/drain regions of the devices. Complementary metal oxide semiconductor (CMOS) technology refers to integrated circuit products that use both n-type and p-type transistor devices.

As stated previously, a CMOS device can include stacked FETS, which may be electrically connected, and/or isolated. Further, manufacturers of CMOS devices, install these devices on wafers, having multiple CMOS devices. The wafer can include a power rail and power distribution network (PDN), which may power the CMOS devices when connected to a power source. The power rail and PDN can be disposed on a backside of the CMOS device, thus referred to as a backside power rail and backside PDN, respectively. Backside power rail and backside power distribution network can be useful for stacked FET.

Further, stacked FET CMOS devices may be useful for many applications, from memory to computer processors. Memory may include read-only memory and random access memory (RAM), for example. More specifically, RAM can include static RAM (SRAM), which is a type of volatile memory having flip-flops that store each bit. With volatile memory, the SRAM stores the bit with a power source, meaning when power is lost, the stored bit is lost. While an SRAM bit cell may be larger than other types of RAM, SRAM can be faster. However, fabricating an SRAM on a wafer having multiple stacked FET CMOS devices can be challenging. The challenges may involve the complexity of routing power and data into the circuits formed of stacked FETS having backside power rails and backside PDN.

### SUMMARY

Embodiments are disclosed for a complementary metal oxide semiconductor (CMOS) device. The CMOS device includes a hybrid cross-couple contact. The hybrid cross-couple contact includes a frontside contact to a gate of the CMOS device. The frontside contact is disposed on a frontside of the CMOS device. The hybrid cross-couple contact includes a source contact to a source of the CMOS device. The source contact is disposed on a backside of the CMOS device. The hybrid cross-couple contact includes a drain contact to a drain of the CMOS device. The drain contact is disposed on a backside of the CMOS device. Advantageously, such embodiments reduce resistance, and are less costly to fabricate than wafers having MRAM cells on a same side of the wafer as the transistors. Advantageously, such embodiments reduce the complexity of routing power and data into the circuits formed of stacked FETS having backside power rails and backside PDN.

Embodiments are disclosed for a complementary metal oxide semiconductor (CMOS) device. The CMOS device includes a hybrid cross-couple contact. The hybrid cross-couple contact forms a node for a static random access memory (SRAM) device. The hybrid cross-couple contact includes a frontside contact to a gate of the CMOS device. The frontside contact is disposed on a frontside of the CMOS device. The hybrid cross-couple contact includes a source contact to a source of the CMOS device. The source contact is disposed on a backside of the CMOS device. The hybrid cross-couple contact includes a drain contact to a drain of the CMOS device. The drain contact is disposed on a backside of the CMOS device. Advantageously, such embodiments reduce resistance, and are less costly to fabricate than wafers having MRAM cells on a same side of the wafer as the transistors. Advantageously, such embodiments reduce the complexity of routing power and data into the circuits formed of stacked FETS having backside power rails and backside PDN.

Embodiments are disclosed for a complementary metal oxide semiconductor (CMOS) device. The CMOS device includes a hybrid cross-couple contact. The hybrid cross-couple contact forms a node for a static random access memory (SRAM) device. The SRAM device comprises a plurality of backside contacts that wire Vdd and Vss power supplies for SRAM from the backside of the CMOS device. The hybrid cross-couple contact includes a frontside contact to a gate of the CMOS device. The frontside contact is disposed on a frontside of the CMOS device. The hybrid cross-couple contact includes a source contact to a source of the CMOS device. The source contact is disposed on a backside of the CMOS device. The hybrid cross-couple contact includes a drain contact to a drain of the CMOS device. The drain contact is disposed on a backside of the CMOS device. Advantageously, such embodiments reduce resistance, and are less costly to fabricate than wafers having MRAM cells on a same side of the wafer as the transistors. Advantageously, such embodiments reduce the complexity of routing power and data into the circuits formed of stacked FETS having backside power rails and backside PDN.

Embodiments are disclosed for a complementary metal oxide semiconductor (CMOS) device. The CMOS device includes a hybrid cross-couple contact. The hybrid cross-couple contact forms a node for a static random access memory (SRAM) device. The SRAM device comprises an 8-way shared GND contact wiring to the backside of the CMOS device. The hybrid cross-couple contact includes a frontside contact to a gate of the CMOS device. The frontside contact is disposed on a frontside of the CMOS device. The hybrid cross-couple contact includes a source contact to a source of the CMOS device. The source contact is disposed on a backside of the CMOS device. The hybrid cross-couple contact includes a drain contact to a drain of the CMOS device. The drain contact is disposed on a backside of the CMOS device. Advantageously, such embodiments reduce resistance, and are less costly to fabricate than wafers having MRAM cells on a same side of the wafer as the transistors. Advantageously, such embodiments reduce the complexity of routing power and data into the circuits formed of stacked FETS having backside power rails and backside PDN.

Embodiments are additionally disclosed for a method to fabricate a semiconductor structure. The method includes performing bottom dummy gate formation. The method further includes performing source-drain (S/D) epitaxy formation. Additionally, the method includes performing a first interlayer dielectric (ILD) formation. The method also includes performing gate cut formation. Further, the method includes performing bottom buried local interconnect placeholder formation. The method additionally includes performing a second ILD formation. Also, the method includes performing middle local interconnect placeholder formation. The method further includes performing wafer bonding on a top channel of the wafer. Additionally, the method includes performing top dummy gate formation. The method also includes performing top S/D epitaxy formation. Further, the method includes performing a first top ILD formation. The method additionally includes performing a top gate cut formation. Also, the method includes forming a replacement metal gate opening. The method further includes performing dummy gate removal. Additionally, the method includes performing release of a silicon-germanium (SiGe) sacrificial layer. The method also includes performing a local interconnect placeholder removal. The method additionally includes performing a replacement gate formation. Further, the method includes performing a late gate cut. The method also includes forming middle of line (MOL) contact trenches. Additionally, the method includes removing a bit line 2 placeholder. Further, the method includes removing a GND placeholder. The method additionally includes removing a drain placeholder. Also, the method includes forming a plurality of MOL contacts. The method further includes forming back end of line (BEOL). Additionally, the method includes performing carrier wafer bonding. The method also includes performing wafer flip. Further, the method includes performing substrate removal. The method additionally includes forming a plurality of backside contacts. Also, the method includes forming a backside power rail. Additionally, the method includes forming a backside power distribution network. Advantageously, such embodiments reduce the complexity of routing power and data into the circuits formed of stacked FETS having backside power rails and backside PDN.

Further aspects of the present disclosure are directed toward computer program products with functionality similar to the functionality discussed above regarding the computer-implemented method. The present summary is not intended to illustrate each aspect of, every implementation of, and/or every embodiment of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 is a block diagram of an example stacked field effect transistor (FET) static random access memory (SRAM) fabrication manager, in accordance with some embodiments of the present disclosure.

FIGS. 2A-1, 2A-2, 2A-3, and 2A-4 are a top view of four cells of a stacked FET with cross-coupling, in accordance with some embodiments of the present disclosure.

FIG. 2B is a top view of a top cell of the stacked FET with cross-coupling, in accordance with some embodiments of the present disclosure.

FIG. 2C is a top view of a bottom cell of the stacked FET with cross-coupling, in accordance with some embodiments of the present disclosure.

FIGS. 3A-3B are process flow charts of a method for fabricating a stacked FET device with cross-coupling, in accordance with some embodiments of the present disclosure.

FIGS. 4A, 4B, 4C, 4D, 4E, 4F, 4G, 4H, 41, 4J, 4K, 4L, 4M, and 4N are example fabrication states of an example stacked FET with cross-coupling, in accordance with some embodiments of the present disclosure.

FIGS. 5A-5B are cross-section views of the top and bottom cells of the stacked FET with cross-coupling, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the embodiments described. On the contrary, the intention is to cover all modifications, equivalents, and alternatives falling within the spirit and scope of the present disclosure.

### DETAILED DESCRIPTION

As stated previously, fabricating an SRAM on a wafer having multiple stacked FET CMOS devices can be challenging. The challenges may involve the complexity of routing power and data into the circuits formed of stacked FETS having backside power rails and backside PDN.

Accordingly, some embodiments of the present disclosure can include a stacked FET 6T SRAM cell, having shared contacts, and four-cell (4×) placement. Having 4 cell placements can mean that the GND contact can be shared by 8 cells, the WL contact can be shared by 4 cells, and the Vdd shared by 4 cells. In this placement, the stacked FET with cross-coupling can share: four contacts for a word line (WL), four contacts for drain (VDD) voltage, and eight contacts for a ground. Such embodiments can include a hybrid cross-couple contact having frontside contact to gates, and backside contacts to source-drain (S/D). In this way, the stacked FET with cross-coupling can provide the relatively faster memory of an SRAM in a stacked FET configuration that can increase the amount of available transistors, in comparison to current SRAM devices. Accordingly, some embodiments of the present disclosure can provide a memory device that represents an improvement over existing SRAM devices. Specifically, such embodiments may reduce wiring resistance, improve device performance, and reduce the complexity of the routing and wiring in the back end of line (BEOL).

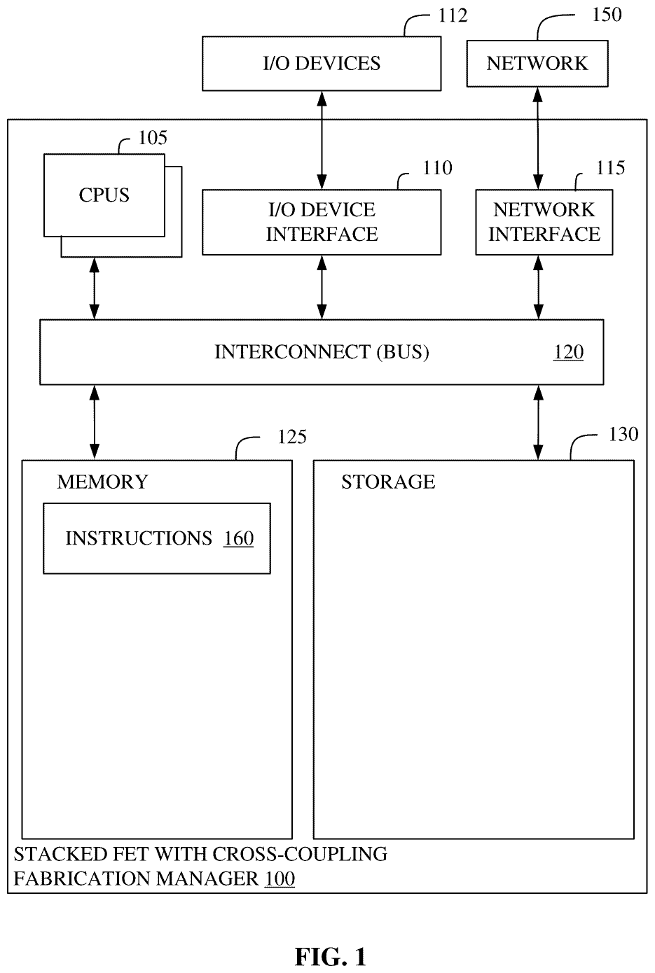

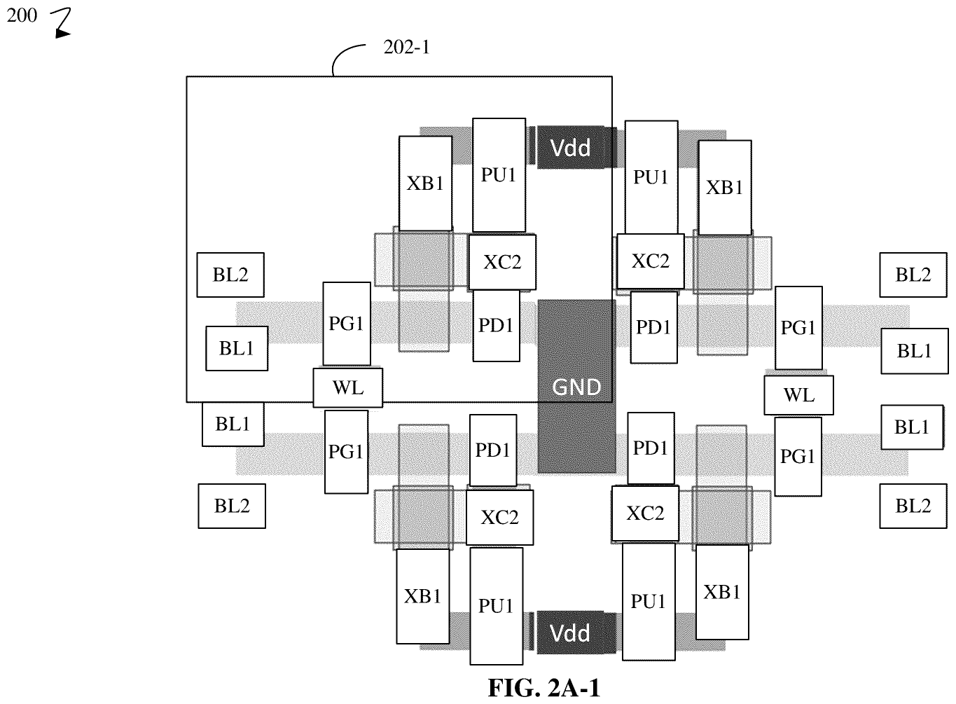

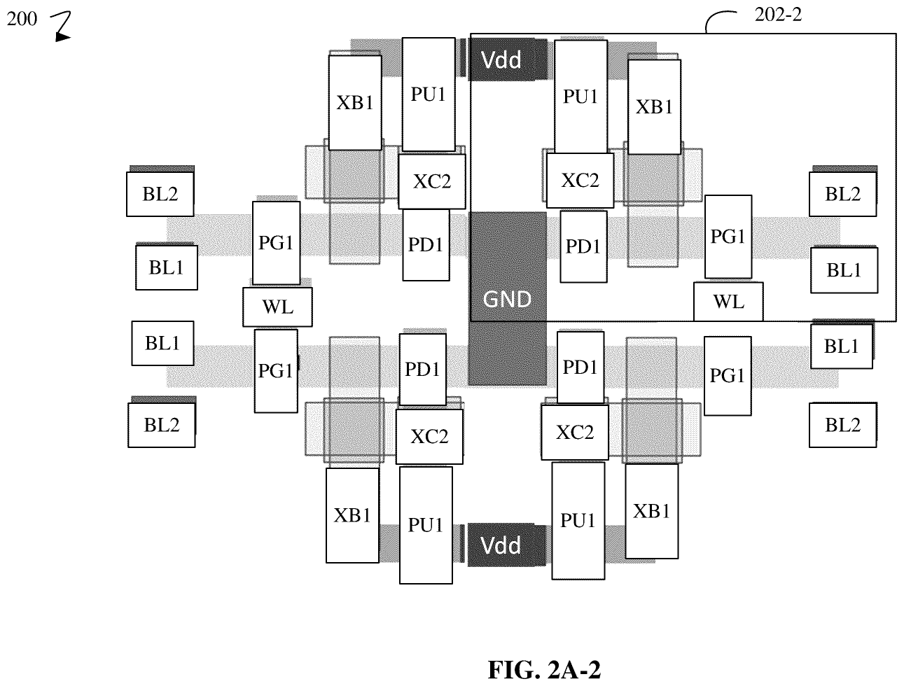

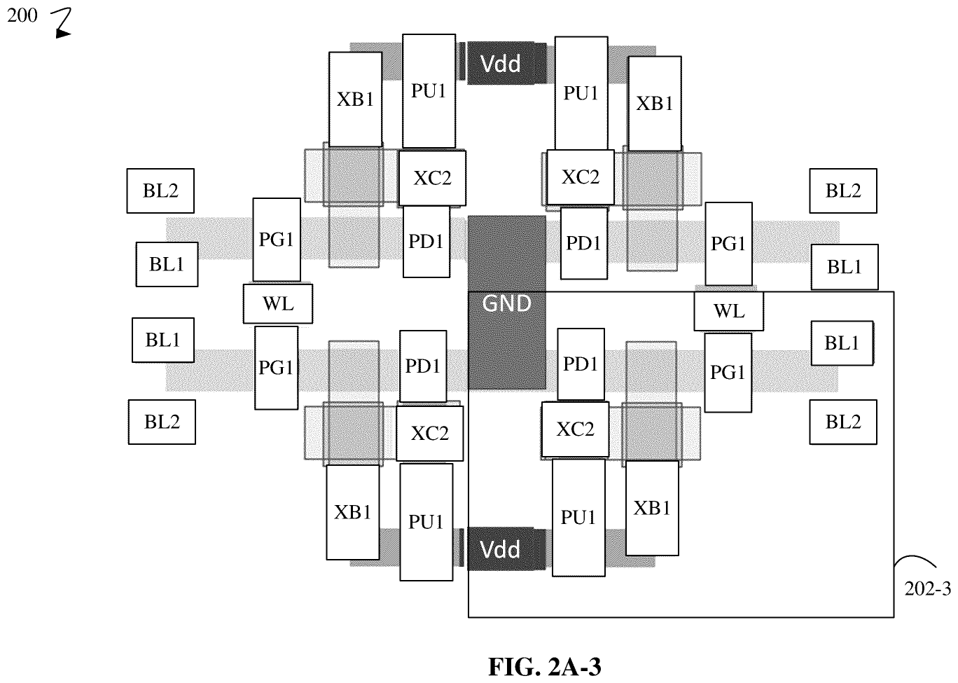

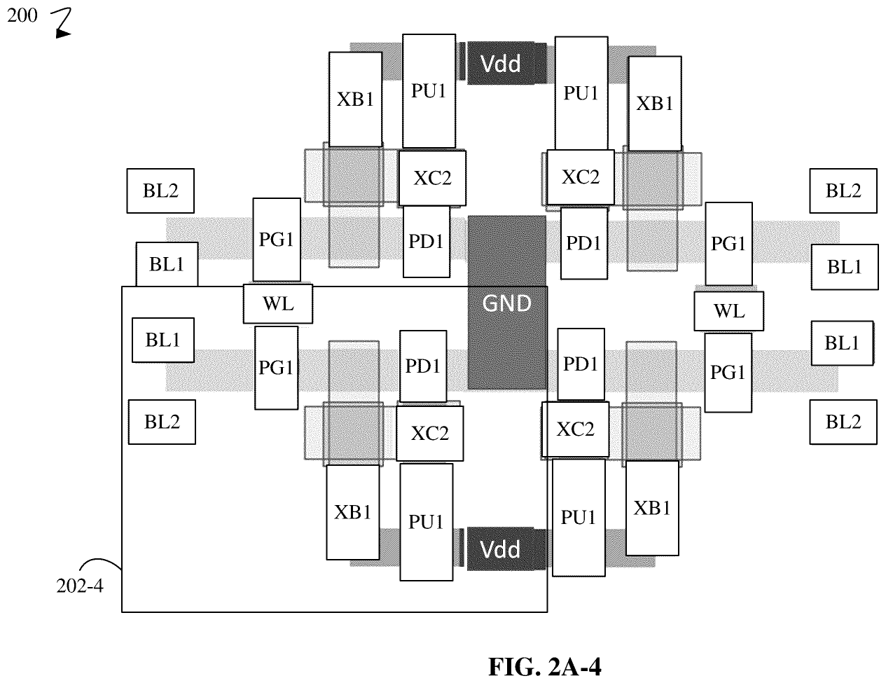

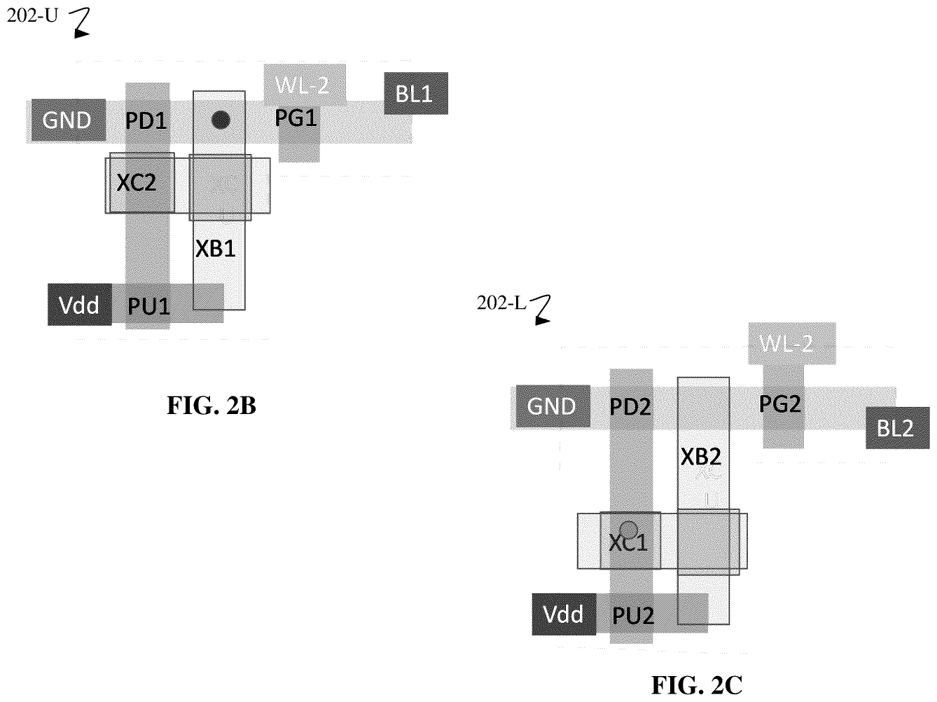

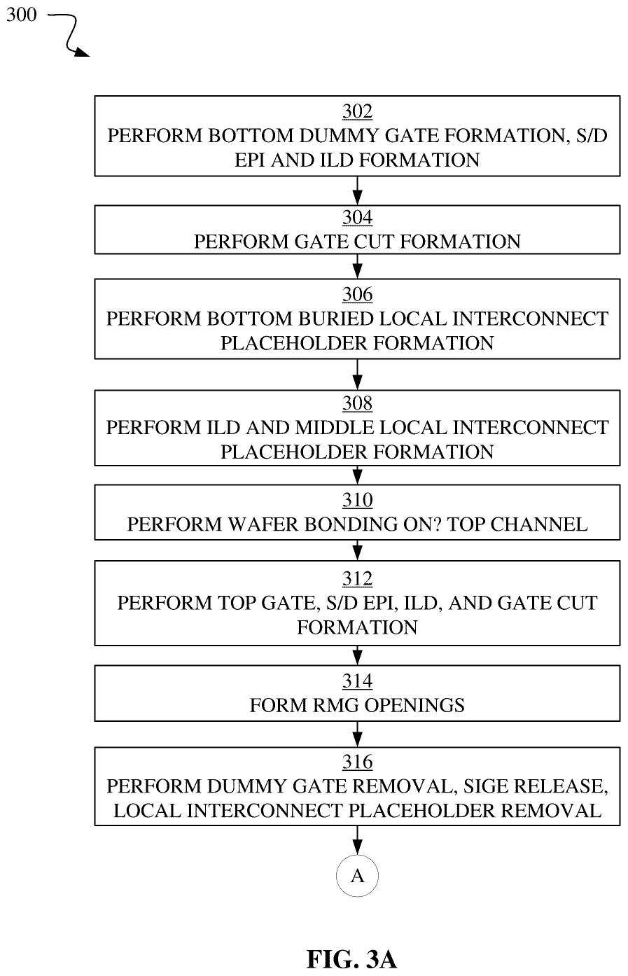

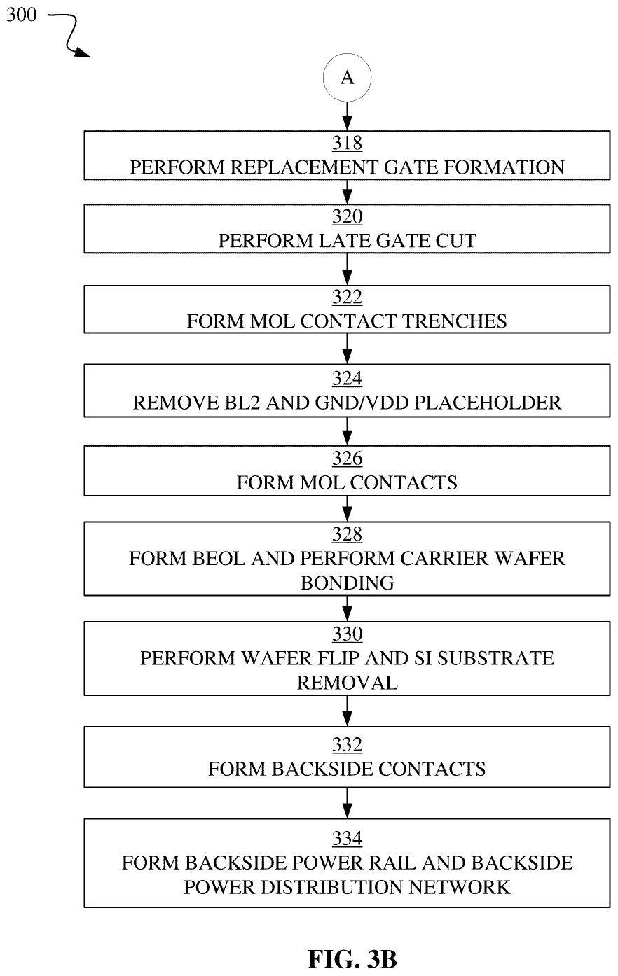

FIG. 1 is a block diagram of an example stacked FET with cross-coupling fabrication manager 100, in accordance with some embodiments of the present disclosure. In various embodiments, the example stacked FET fabrication manager 100 can perform the method described in FIGS. 3A-3B, and/or cause one or more machines to design, fabricate, and/or utilize components as discussed in FIGS. 2A1-2A4, 2B, 2C, 4A-4N, and 5A-5B. In some embodiments, the example stacked FET fabrication manager 100 provides instructions for the aforementioned methods and/or functionalities to a client machine such that the client machine executes the method, or a portion of the method, based on the instructions provided by the example stacked FET fabrication manager 100. In some embodiments, the example stacked FET fabrication manager 100 comprises software executing on hardware incorporated into a plurality of devices.

The example stacked FET fabrication manager 100 includes a memory 125, storage 130, an interconnect (e.g., BUS) 120, one or more CPUs 105 (also referred to as processors 105 herein), an I/O device interface 110, I/O devices 112, and a network interface 115.

Each CPU 105 retrieves and executes programming instructions stored in the memory 125 or the storage 130. The interconnect 120 is used to move data, such as programming instructions, between the CPUs 105, I/O device interface 110, storage 130, network interface 115, and memory 125. The interconnect 120 can be implemented using one or more busses. The CPUs 105 can be a single CPU, multiple CPUs, or a single CPU having multiple processing cores in various embodiments. In some embodiments, a CPU 105 can be a digital signal processor (DSP). In some embodiments, CPU 105 includes one or more 3D integrated circuits (3DICs) (e.g., 3D wafer-level packaging (3DWLP), 3D interposer based integration, 3D stacked integrated circuits (3D-SICs), monolithic 3D integrated circuits, 3D heterogeneous integration, 3D system in package (3DSiP), and/or package on package (PoP) CPU configurations). Memory 125 is generally included to be representative of a random access memory (e.g., static random access memory (SRAM), dynamic random access memory (DRAM), or Flash). The storage 130 is generally included to be representative of a non-volatile memory, such as a hard disk drive, solid state device (SSD), removable memory cards, optical storage, and/or flash memory devices. Additionally, the storage 130 can include storage area-network (SAN) devices, the cloud, or other devices connected to the example stacked FET fabrication manager 100 via the I/O device interface 110 or to a network 150 via the network interface 115.

In some embodiments, the memory 125 stores instructions 160. However, in various embodiments, the instructions 160 are stored partially in memory 125 and partially in storage 130, or they are stored entirely in memory 125 or entirely in storage 130, or they are accessed over a network 150 via the network interface 115.

Instructions 160 can be processor-executable instructions for performing any portion of, or all, any of the methods described in FIGS. 3A-3B, and/or cause one or more machines to design, fabricate, and/or utilize components as discussed in FIGS. 2A1-2A4, 2B, 2C, 4A-4N, and 5A-5B.

In various embodiments, the I/0 devices 112 include an interface capable of presenting information and receiving input. For example, I/0 devices 112 can present information to a listener interacting with example stacked FET fabrication manager 100 and receive input from the listener.

The example stacked FET fabrication manager 100 is connected to the network 150 via the network interface 115. Network 150 can comprise a physical, wireless, cellular, or different network.

In some embodiments, the example stacked FET fabrication manager 100 can be a multi-user mainframe computer system, a single-user system, or a server computer or similar device that has little or no direct user interface but receives requests from other computer systems (clients). Further, in some embodiments, the example stacked FET fabrication manager 100 can be implemented as a desktop computer, portable computer, laptop or notebook computer, tablet computer, pocket computer, telephone, smart phone, network switches or routers, or any other appropriate type of electronic device.

It is noted that FIG. 1 is intended to depict the representative major components of an example stacked FET fabrication manager 100. In some embodiments, however, individual components can have greater or lesser complexity than as represented in FIG. 1, components other than or in addition to those shown in FIG. 1 can be present, and the number, type, and configuration of such components can vary.

FIGS. 2A-1 through 2A-4 describe four cells of an upper level of a stacked FET with cross-coupling having two levels of such cells. The cells are semiconductor device cells having similar elements. Additionally, each of the cells, can be configured and positioned to share common elements, more specifically, the ground, drain, word lines, and bit lines. In this way, some embodiments of the present disclosure may reduce the potential wiring of the stacked FET with cross-coupling. Further, such embodiments may thus provide an improved semiconductor device. The ground and drain may provide electric current ground and drains to the cells. Additionally, the word lines and bit lines may be lengths of electrically conductive material configured to read/write bits and words of the cells. The specific configuration of each of the cells is described in greater detail below.

FIG. 2A-1 is a top view of an upper level of a stacked FET with cross-coupling 200, in accordance with some embodiments of the present disclosure. More specifically, the stacked FET with cross-coupling 200 includes cell 202-1. The cell 202-1 is one of four similar cells shown, in this level of the stacked FET with cross-coupling 200. The cell 202-1 includes a bit line 1 (BL1), bit line 2 (BL2), word line (WL), p-type gate 1 (PG1), cross-connect B1 (XB1), pull up 1 (PU1), cross-connect C1, (XC2), power dissipation 1 (PD1), drain (Vdd), and ground (GND).

FIG. 2A-2 is a top view of a layer of a stacked FET with cross-coupling 200, in accordance with some embodiments of the present disclosure. More specifically, the stacked FET with cross-coupling 200 includes cell 202-2, which is similar to cell 202-1.

FIG. 2A-3 is a top view of a layer of a stacked FET with cross-coupling 200, in accordance with some embodiments of the present disclosure. More specifically, the stacked FET with cross-coupling 200 includes cell 202-3, which is similar to cell 202-1.

FIG. 2A-4 is a top view of a layer of a stacked FET with cross-coupling 200, in accordance with some embodiments of the present disclosure. More specifically, the stacked FET with cross-coupling 200 includes cell 202-4, which is similar to cell 202-1. For clarity, the cells 202-1, 202-2, 202-3, 202-4 are collectively referred to as cells 202.

According to some embodiments of the present disclosure, the stacked FET with cross-coupling 200 can include a ground (GND), drains (Vdd), word lines (WL) and bit lines (BL1, BL2). Further, each of the cells 202-1, 202-2, 202-3, 202-4, and the cells (not shown) disposed beneath these cells in the lower level (not shown) can be configured and positioned to share the ground (GND), drain (Vdd), word lines (WL), and bit lines (BL1, BL2) in a manner that reduces the potential for wiring this many cells. More specifically, the GND may provide the electrical current ground for the cells 202-1, 202-2, 202-3, 202-4 and the cells (not shown) disposed beneath these cells.

Additionally, stacked FET with cross-coupling 200 may include drains Vdd-1, Vdd-2, wherein, the drain Vdd-1 may provide electrical current drain for cells 202-1, 202-2, and the cells (not shown) of the lower level, disposed beneath cells 202-1, 202-2. Further, the drain Vdd-2 may provide electrical current drain for the cells 202-3, 202-4, and the cells (not shown) disposed beneath these cells.

Further, the stacked FET with cross-coupling 200 may include word lines WL-1, WL-2, where the cells 202-1, 202-4, and the cells disposed beneath these cells, can share WL-1. Similarly, the cells 202-2, 202-3, and the cells disposed beneath these cells, can share WL-2.

Additionally, the stacked FET with cross-coupling 200 can include four sets of bit lines BL1, BL2. Further, each of the cells 202-1, 202-2, 202-3, 202-4 can share a set of bit lines BL1, BL2 with the cell disposed beneath the cell. Thus, the cell 202-1 shares bit lines (BL1, BL2) with the cell disposed beneath the cell 202-1 in the lower level of the stacked FET with cross-coupling, and the like.

FIG. 2B is a top view of an upper level cell 202-U of the stacked FET with cross-coupling 200, in accordance with some embodiments of the present disclosure. The upper level cell 202-U can be similar to the cells 202, described with respect to FIGS. 2A-1 through 2A-4.

FIG. 2C is a top view of a lower level cell 200-L of the stacked FET with cross-coupling 200, in accordance with some embodiments of the present disclosure. According to some embodiments of the present disclosure, the lower level cell 200-L can be similar to the upper level cell 200-U, and disposed beneath the upper level cell 202-U. In this way, the stacked FET with cross-coupling 200 may enable sharing ground (GND), word line (WL), and bit lines (BL1, BL2) as described with respect to FIGS. 2A-1 through 2A-4. According to some embodiments of the present disclosure, the upper level cell 200-U and 200-L can include self-aligned contacts, which are formed to provide overlay and dimensional control tolerance to assure connection with XB2.

FIGS. 3A-3B are process flow charts of a method 300 for fabricating a stacked FET with cross-coupling, in accordance with some embodiments of the present disclosure. In some embodiments, an example stacked FET with cross-coupling fabrication manager, such as the example stacked FET with cross-coupling fabrication manager 100 described with respect to FIG. 1, can perform the method 300.

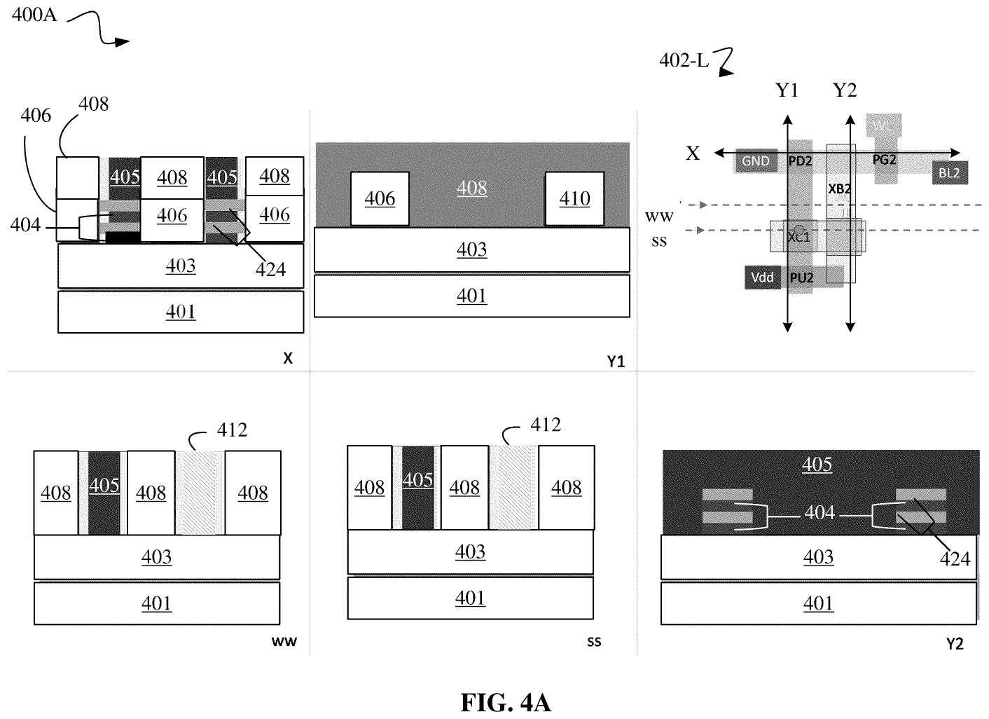

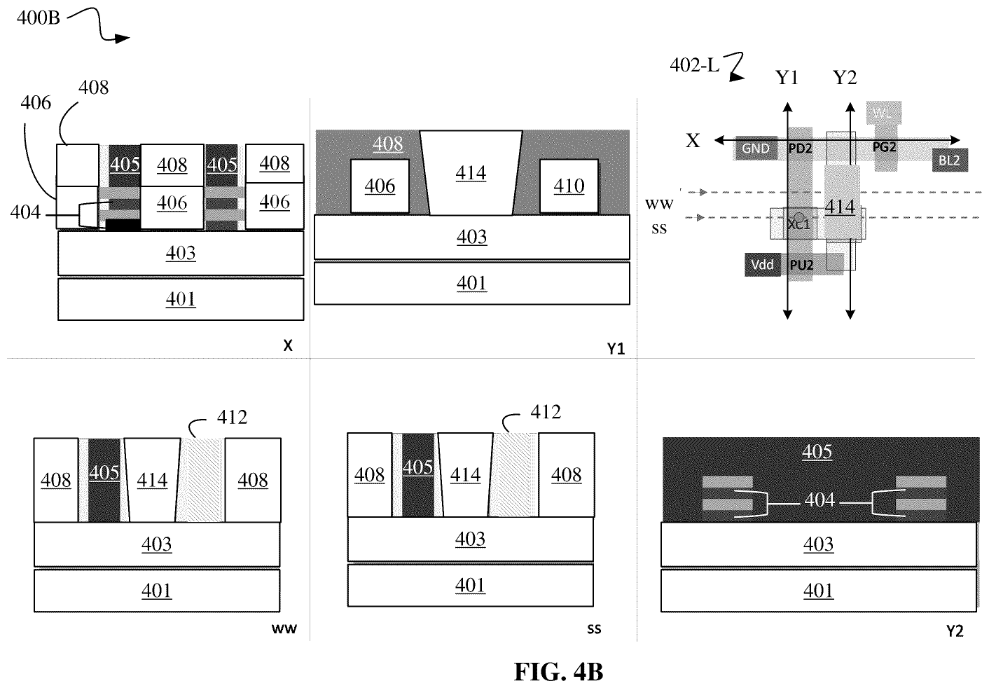

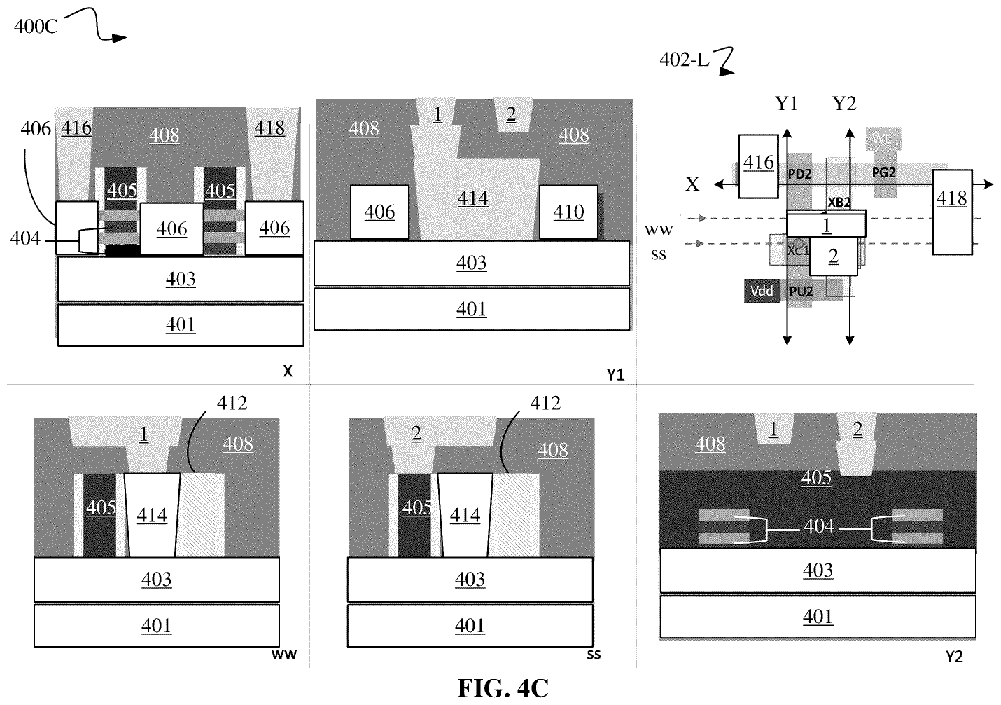

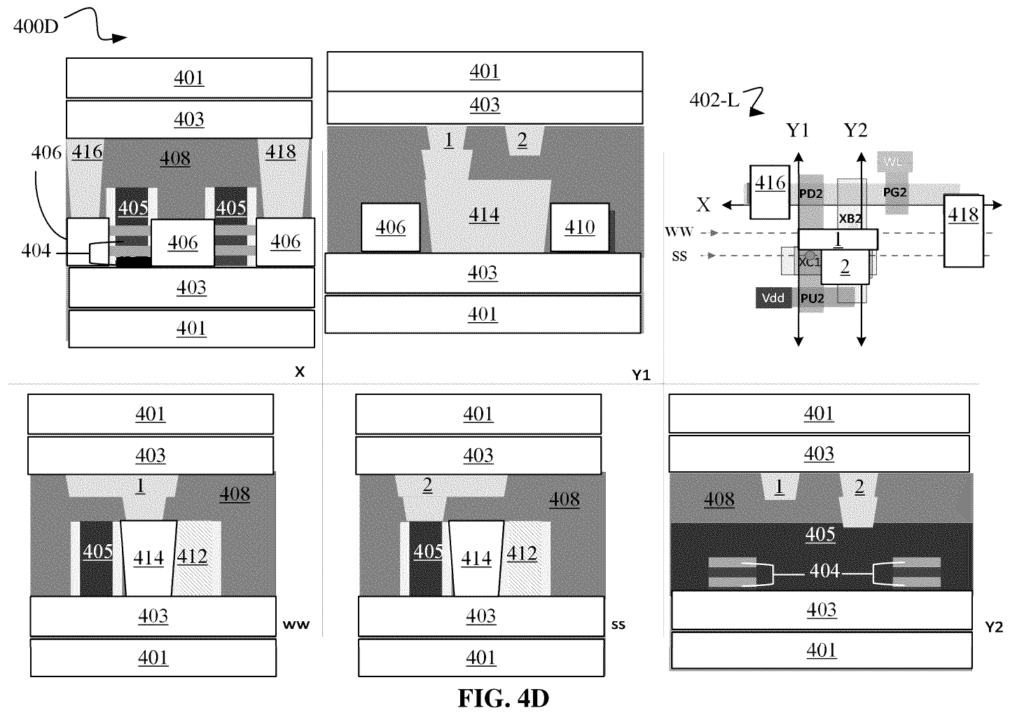

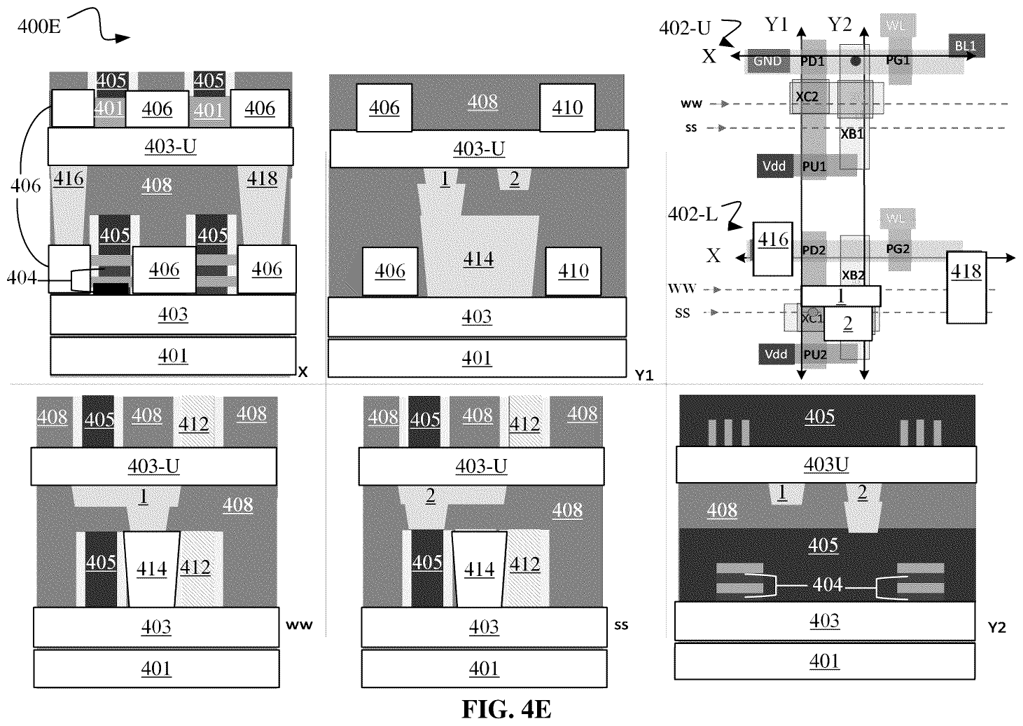

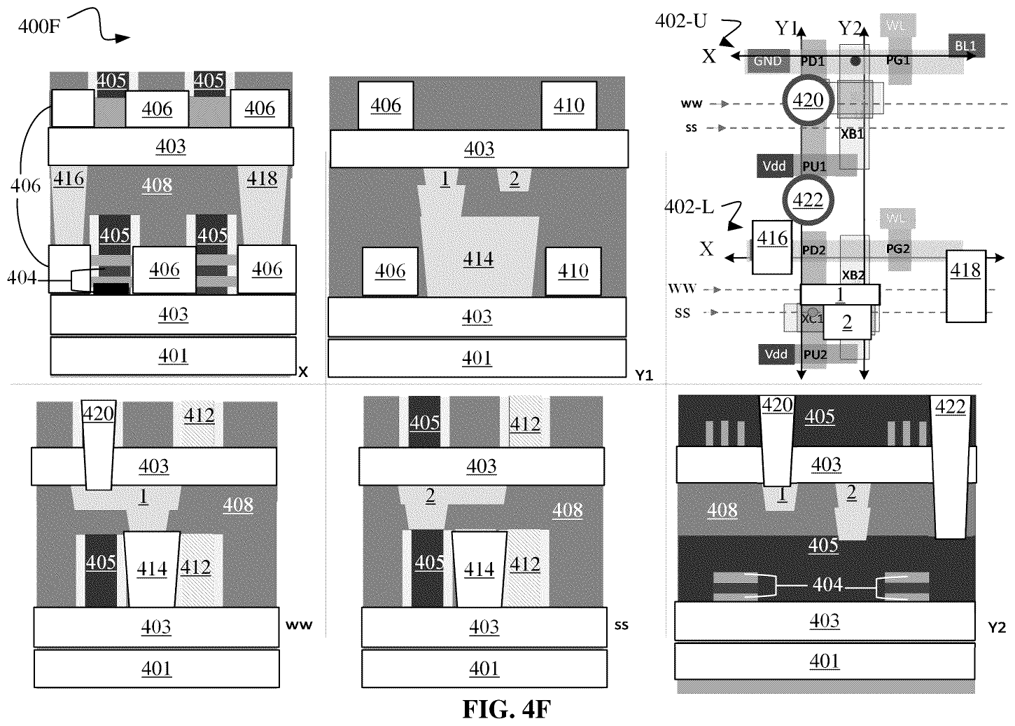

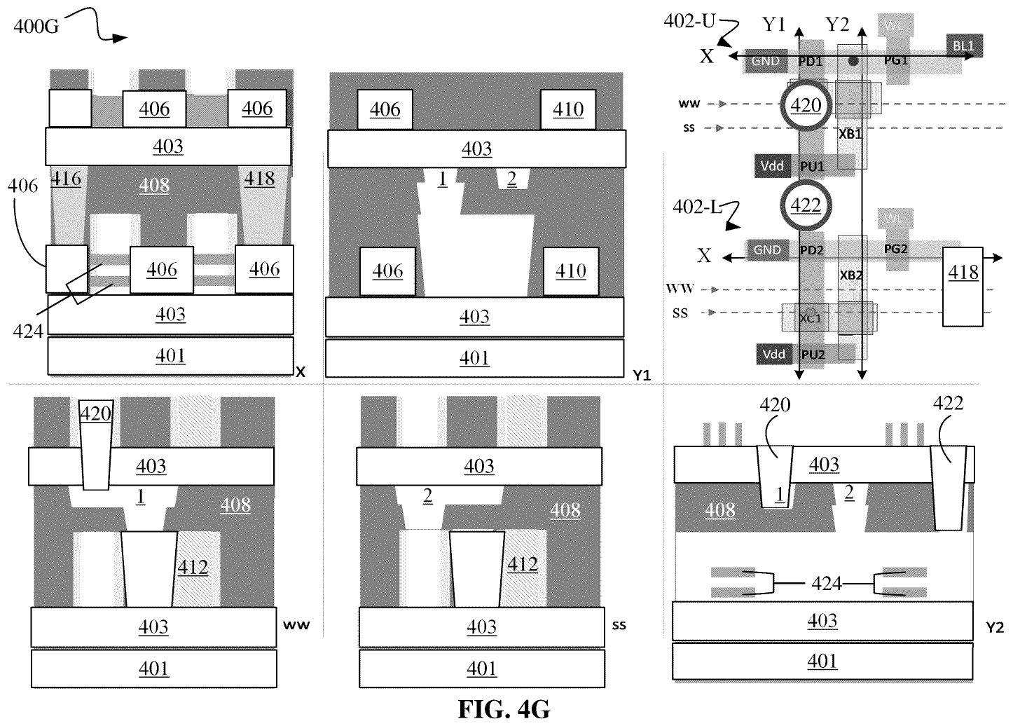

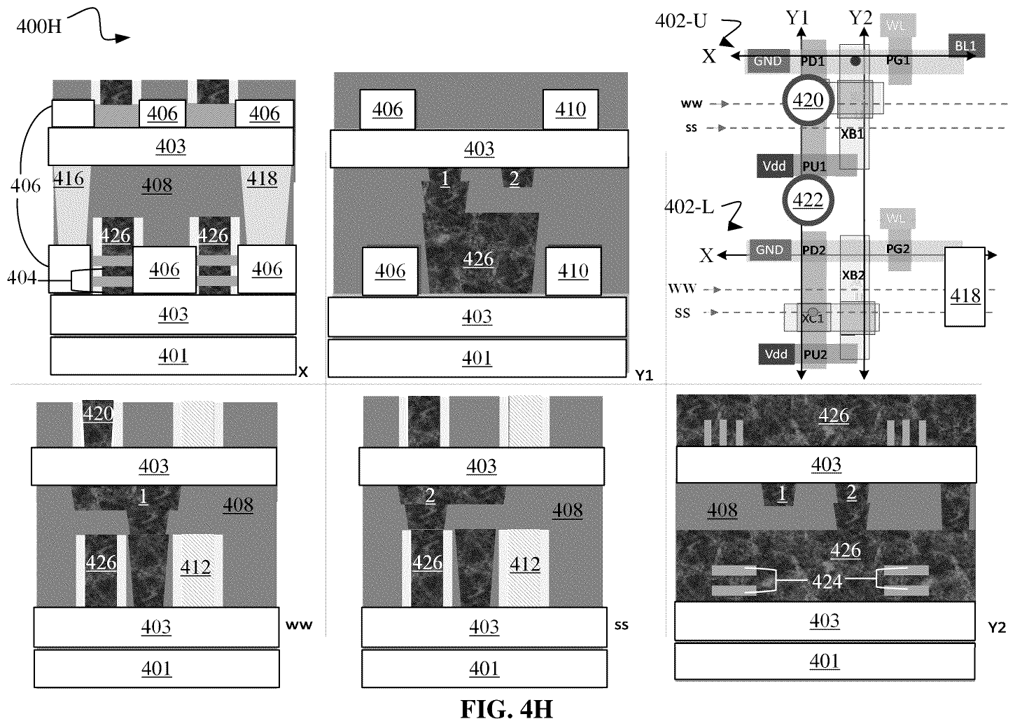

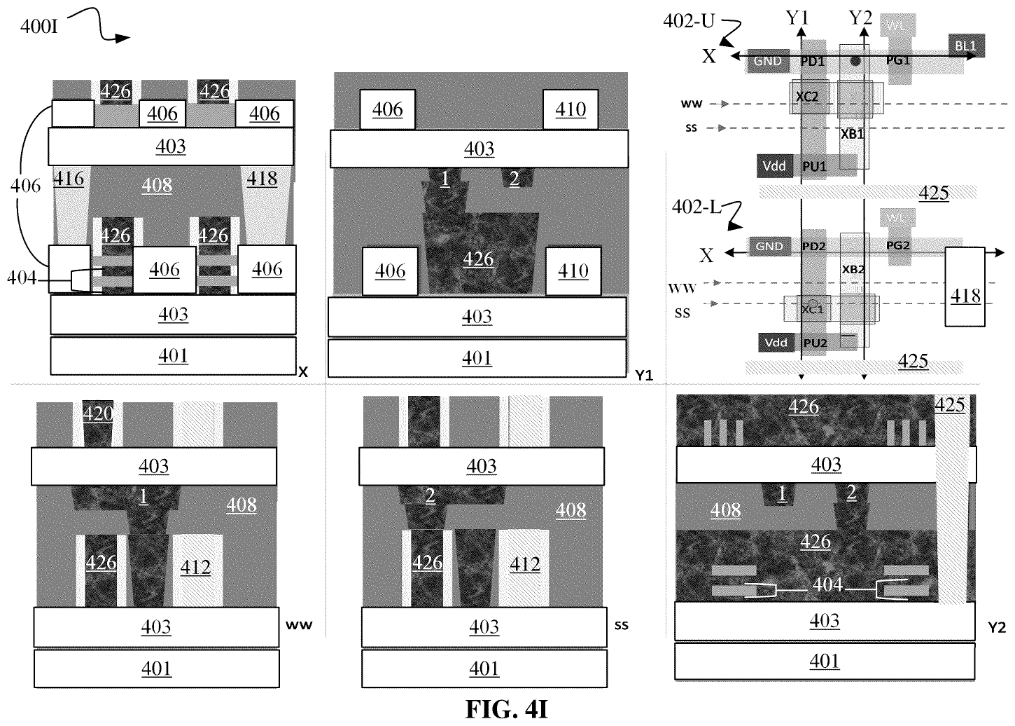

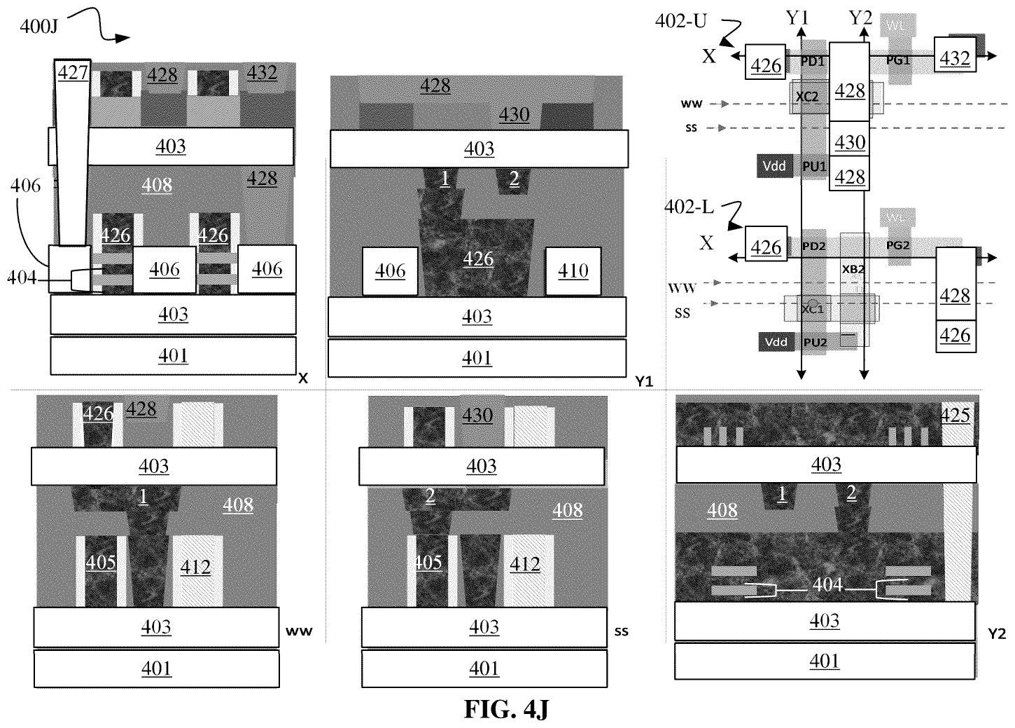

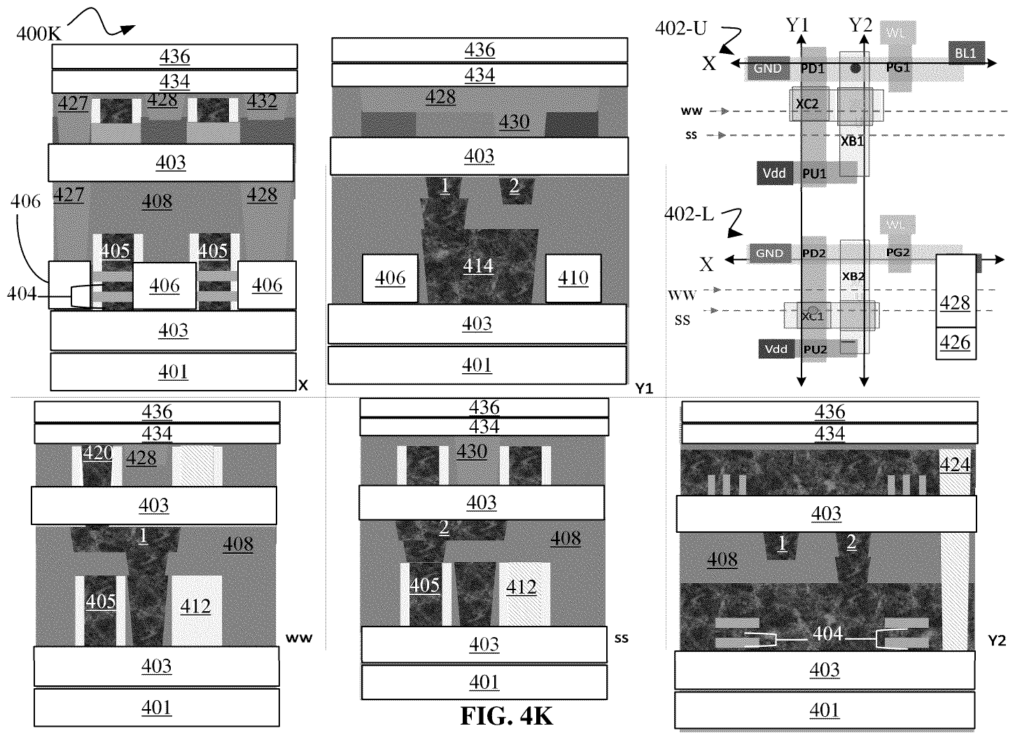

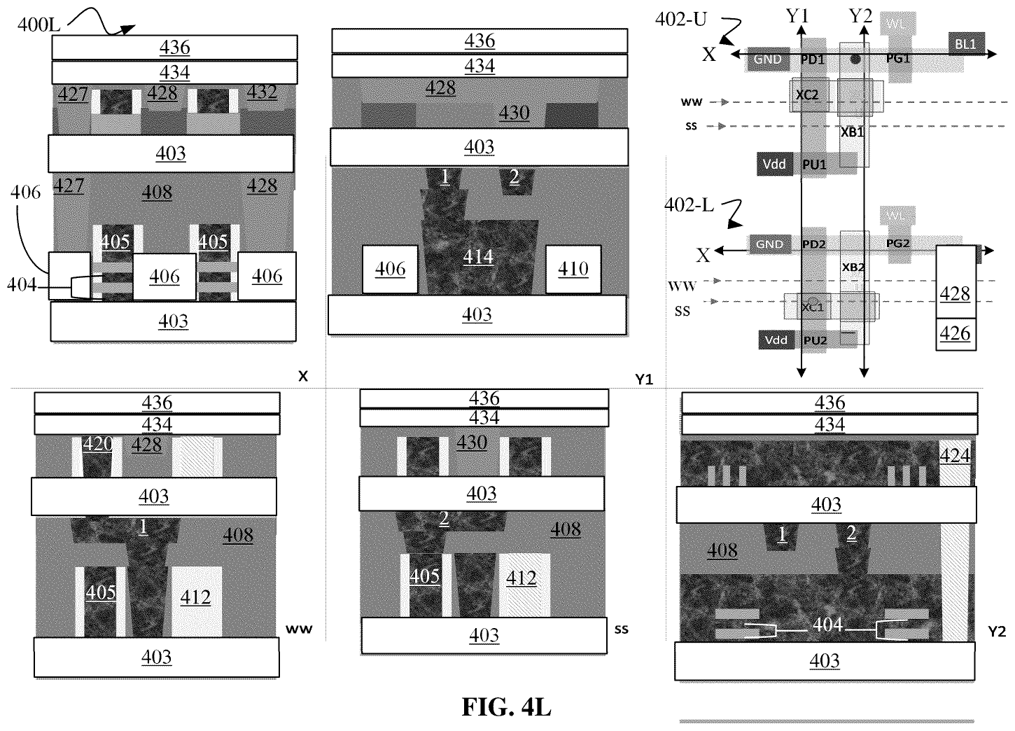

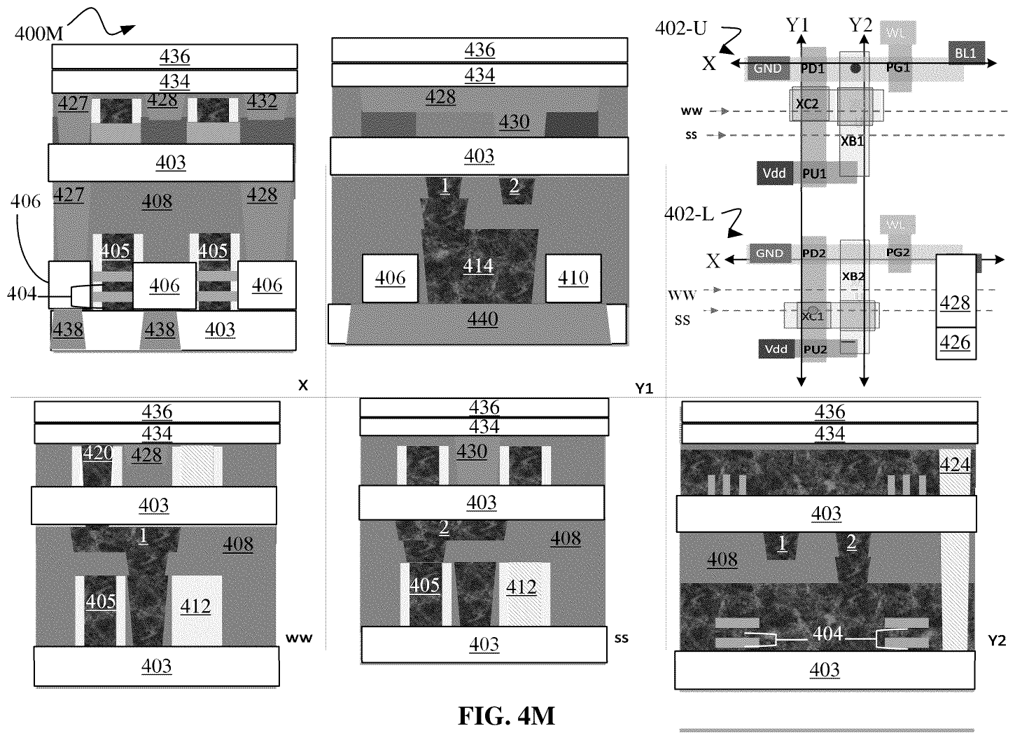

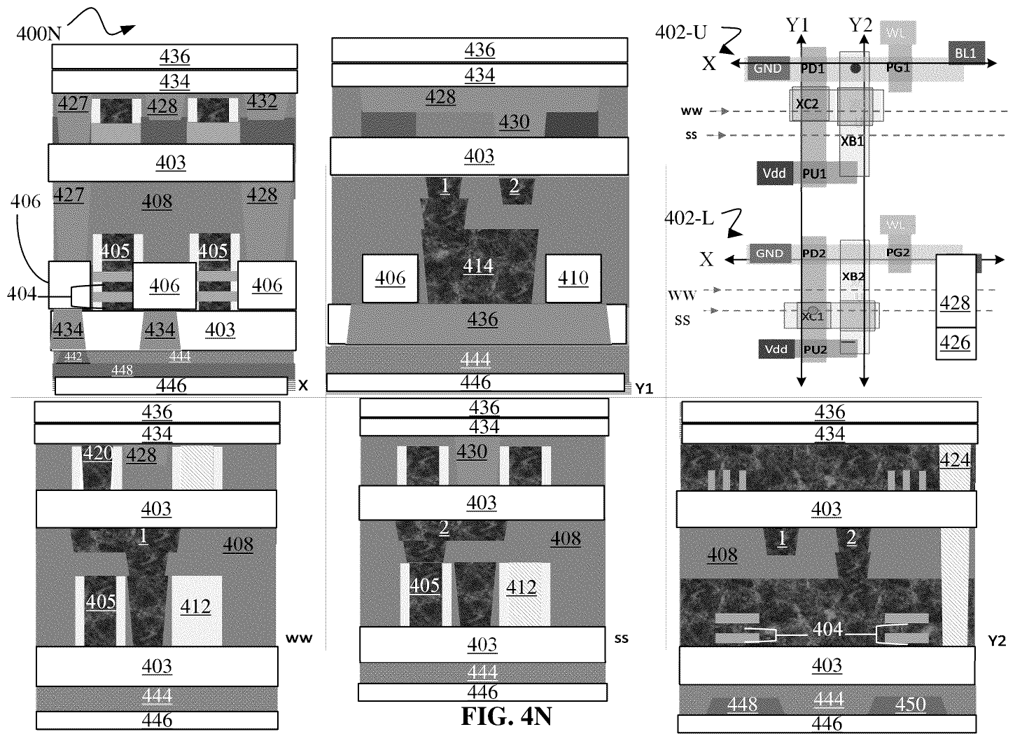

FIG. 3A is a process flow chart of operations 302 through 316 of the method 300, in accordance with some embodiments of the present disclosure. For clarity, these operations are described with respect to FIGS. 4A through 4G.

FIGS. 4A-4N represent example fabrication states of a stacked FET with cross-coupling, e.g., the stacked FET with cross-coupling 200, described with respect to FIGS. 2A-1-2A-4. The FIGS. 4A-4N include six panels, each providing a view of the cell(s) of the stacked FET with cross-coupling. The top right panel shows a top view of the fabricated cell(s), e.g., cell 202. Additionally, the top right panel shows cut lines, X, Y1, Y2, ww, and ss on the fabricated cell(s). Accordingly, each of the remaining panels shows a cross section of the cell(s) from the view of the corresponding cut line. For example, the top left panel, view X, shows a cross section of the cell(s), along cut line X. Similarly, the views Y1, Y2, ww, and ss show cross-section views of the cell(s) along cut lines Y1, Y2, ww, and ss. In this way, the example fabrication states can represent the cell(s) after the operations of the method 300.

FIG. 4A is an example fabrication state 400A of a stacked FET with cross-coupling, according to some embodiments of the present disclosure. The example fabrication state 400A may represent the state of a cell of the stacked FET with cross-coupling after operations 302 and 304. In the example fabrication state, 400A, the top right panel shows the top view of a cell of the stacked FET with cross-coupling, e.g., cell 402-L. The cell 402-L may be similar to the cell 202-L described with respect to FIG.2C.

In view X, the cell 402-L may include substrate 401, BOX 403, sacrificial SiGe layer 404, hard mask 405, source-drain epitaxy (S/D epi) 406, and interlayer dielectric (ILD) 408. More specifically, the substrate 401 can represent a layer of dielectric material such as, silicon nitride (SiN). Further, the BOX 403 can represent an isolation layer, and can be composed of silicon dioxide (SiO 2). Additionally, the sacrificial SiGe layer 404 can be a layer of SiGe that serves as a placeholder for a gate to be fabricated. Accordingly, the sacrificial SiGe layer 404 surrounds the channels 424 of the cell 402-L, similar to a gate. To protect the sacrificial SiGe layer 404, the hard mask 405 can provide a cap. Further, the S/D epi 406 can represent a single crystal lattice structure across an interface. Additionally, the ILD 408 may be a dielectric material with a relatively low-k constant (e.g., k=3.9 or less) that electrically separates relatively close interconnect lines arranged in several levels. The low k dielectric material can mitigate capacitive coupling between neighboring interconnect lines.

The cut line Y1 is cut along the source-drain (S/D) of the cell 402-L. As shown in view Y1, the cell 402-L may include substrate 401, BOX 403, sacrificial SiGe layer 404, hard mask 405, S/D epi 406, ILD 408, and S/D epi 410. According to some embodiments of the present disclosure, the S/D epi 406 can be an n-type epitaxy, and the S/D epi 410 can be a p-type epitaxy.

The cut line Y2 is cut along the gate of the cell 402-L. As shown in view Y2, the cell 402-L may include the substrate 401, BOX 403, sacrificial SiGe layer 404, hard mask 405, and channels 424. According to some embodiments of the present disclosure, the S/D epi 410 can be a p-type epitaxy.

In the view ww, the cell 402-L includes the substrate 401, BOX 403, hard mask 405, ILD 408, and gate cut 412. The gate cut 412 can represent a trench cut into the ILD 408 by a fabrication tool. The gate cut 412 can provide access later in the fabrication process to build a gate.

In the view ss, the cell 402-L includes the substrate 401, BOX 403, hard mask 405, ILD 408, and gate cut 412. Similar to the view ww, the view ss shows the gate cut 412 with respect to the hard mask 405.

Referring back to FIG. 3A, at operation 302, the stacked FET with cross-coupling fabrication manager 100 can direct a fabrication tool to perform bottom dummy gate formation, S/D epi formation, and ILD formation. Dummy gate formation can involve depositing sacrificial layers that serve as placeholders for gates. More specifically, dummy gate formation can include depositing SiGE, e.g., sacrificial SiGe layer 404, on a BOX layer, e.g., BOX 403. Additionally, dummy gate formation can involve depositing the hard mask 405 on the sacrificial SiGe layer 404. Accordingly, the sacrificial SiGe layer 404 and hard mask 405 may represent the bottom dummy gate formed in operation 302.

It is noted that the views ww, ss show a dummy gate and the gate cut 412. However, as stated previously, example fabrication state 400A represents the cell 402-L after operation 304. As such, the gate cut 412 appears in place of a dummy gate removed by the gate cut formation. Thus, the dummy gate formation can include the formation of two dummy gates, with the second dummy gate occupying the space represented by the gate cut 412.

The S/D epitaxy formation can involve growing the S/D epitaxy, e.g., S/D epi 406 on the BOX 403, in pillars surrounding the dummy gates. The ILD formation can involve depositing the ILD 408 on the S/D epi 406.

At operation 304, the example stacked FET with cross-coupling fabrication manager 100 may direct a fabrication tool to perform gate cut formation. Performing gate cut formation can involve cutting one of the dummy gates.

FIG. 4B is a block diagram of an example fabrication state 400B of a stacked FET with cross-coupling, in accordance with some embodiments of the present disclosure. The example fabrication state 400B can represent the cell 402-L after operation 306. In comparison to example fabrication state 400A, the views X and Y2 are unchanged in example fabrication state 400B.

In contrast, as shown in the cell 402-L in the upper right hand panel of example fabrication state 400B, the cell 402-L includes a bottom buried local interconnect placeholder 414, which is shown in greater detail in view Y1. As shown in view Y1, the cell 402-L includes the same elements as described in example fabrication state 400A. Referring back to FIG. 4B, in view Y1, the cell 402-L includes the bottom buried local interconnect placeholder 414. The bottom buried local interconnect placeholder 414 can be a deposit, such as, silicon (Si) that serves as a placeholder for a local interconnect to be buried in the ILD 408 later in the fabrication process. Similarly, views ww and ss include the same elements as described in example fabrication state 400A, with exception to the middle ILD 408. In example fabrication state 400B, the middle ILD 408 is replaced with the bottom buried local interconnect placeholder 414.

Referring back to FIG. 3A, at operation 306, the stacked FET with cross-coupling fabrication manager 100 can direct the fabrication tool to perform bottom buried local interconnect placeholder formation. Forming the bottom buried local interconnect placeholder 414 can involve forming a trench by removing dielectric material 408 from the cell 402-L, and depositing silicon in the formed trench.

FIG. 4C is a block diagram of an example fabrication state 400C of a stacked FET with cross-coupling, in accordance with some embodiments of the present disclosure. The example fabrication state 400C can represent the cell 402-L after operation 308.

As shown in the top right panel, the cell 402-L includes the GND placeholder 416, BL2 placeholder 418, local interconnect placeholder 1, and local interconnect placeholder 2. Accordingly, as shown in view X, the cell 402-L includes the substrate 401, BOX 403, sacrificial SiGe layer 404, hard mask 405, S/D epis 406, ILD 408, GND placeholder 416, and BL2 placeholder 418. The GND placeholder 416 and BL2 placeholder 418 can be deposits of silicon that occupy spaces where the fabrication tool can fabricate the GND and BL2, respectively.

Further, in view Y1, the cell 402-L includes the substrate 401, BOX 403, S/D epi 406 (e.g., n-type), S/D epi 410 (e.g., p-type), bottom buried local interconnect placeholder 414, and local interconnect placeholders 1 and 2. The local interconnect placeholders 1, 2 can be trenches cut into the ILD 408 to provide a space to fabricate local interconnects to the gates of the cell 402-L. With respect to view Y2, the cell 402-L includes the substrate 401, BOX 403, sacrificial SiGe layer 404, hard mask 405, ILD 408, and local interconnect placeholders 1 and 2.

Additionally, in view ww, the cell 402-L includes the substrate 401, BOX 403, hard mask 405, ILD 408, gate cut 412, bottom buried local interconnect placeholder 414, and local interconnect placeholder 1. Also, in view ss, the cell 402-L includes the substrate 401, BOX 403, hard mask 405, ILD 408, gate cut 412, bottom buried local interconnect placeholder 414, and local interconnect placeholder 2.

Referring back to FIG. 3A, at operation 308, the stacked FET with cross-coupling fabrication manager 100 can direct the fabrication tool to perform ILD and middle local interconnect placeholder formation. Performing ILD formation can involve depositing ILD material, e.g., ILD 408, on the S/D epitaxies 406. Additionally, forming the middle local interconnect placeholders can involve forming trenches by removing some of the deposited ILD 408 in the areas represented by the GND placeholder 416, BL2 placeholder, and local interconnect placeholders 1, 2, and depositing silicon in the formed trenches.

FIG. 4D is a block diagram of an example fabrication state 400D of an example stacked FET with cross-coupling, in accordance with some embodiments of the present disclosure. The example fabrication state 400D can represent the cells 402-U, 402-L after operation 310. In comparison to example fabrication state 400C, the views X, Y1, Y2, ww, and ss are the same, with exception to the additional BOX 403 and substrate layer 401.

At operation 310, the stacked FET with cross-coupling fabrication manager 100 can direct the fabrication tool to perform wafer bonding on the top channel. The top channel can represent the layers of the cell, e.g., 402-U. Thus, performing wafer bonding on the top channel can involve depositing another buried oxide layer, e.g., BOX 403-U, and substrate layer, e.g., 401, on the cell 402-L.

FIG. 4E is a block diagram of an example fabrication state 400E of an example stacked FET STRAM, in accordance with some embodiments of the present disclosure. The example fabrication state 400E can represent the cells 402-U, 402-L after operation 312.

In comparison to example fabrication state 400D, the views X, Y1, Y2, ww, and ss are the same with respect to the cell 402-L. However, with respect to cell 402-U, view X shows the cell 402-U includes substrate 401, BOX 403-U, hard mask 405, and S/D epi 406. Together, the substrate 401 and hard mask 405 may represent the top dummy gate formed in operation 312.

In view Y1, the cell 402-U includes BOX 403-U, S/D epis 406, 410, and ILD 408. In view Y2, the cell 402-U includes the substrate 401, BOX 403-U, and hard mask 405.

As shown in the view ww, the cell 402-U includes the BOX 403-U, hard mask 405, ILD 408, and gate cut 412. In the view ss, the cell 402-U includes the BOX 403-U, hard mask 405, ILD 408, and gate cut 412.

Referring back to FIG. 3A, at operation 312, the stacked FET with cross-coupling fabrication manager 100 can direct the fabrication tool to perform top dummy gate, S/D EPI, ILD, and gate cut formation. According to some embodiments of the present disclosure, the operation 312 can be similar to the operations 302 and 304. In this way, the operation 312 can represent fabricating an upper level cell 402-U, similar to the upper level cell 202-U, described with respect to FIG. 2B.

FIG. 4F is a block diagram of an example fabrication state 400F of a stacked FET with cross-coupling, in accordance with some embodiments of the present disclosure. The example fabrication state 400F can represent the cells 402-U, 402-L after operation 314. In the upper right panel, the cell 402-U includes replacement metal gate (RMG) openings 420, 422. The RMG openings 420, 422, provide a space to fabricate replacement metal gates. For the cells 402-U, 402-L.

In comparison to example fabrication state 400E, the views X, Y1, ss, are unchanged with respect to the cells 402-L, 402-U. However, with respect to view ww, the cell 402-U additionally includes RMG opening 420. Further, with respect to the view Y2, the cell 402-U additionally includes RMG openings 420, 422. Additionally, the RMG opening 422 extends to the hard mask 405 of the cell 402-L.

Referring back to FIG. 3A, at operation 314, the stacked FET with cross-coupling fabrication manager 100 can direct the fabrication tool to form the RMG openings 420, 422. Forming the RMG openings 420, 422 can involve removing material at the locations of the RMG openings 420, 422.

At operation 316, the stacked FET with cross-coupling fabrication manager 100 can direct the fabrication tool to perform dummy gate removal, SiGe release, and local interconnect placeholder removal. Accordingly, the fabrication tool may remove the dummy gates, e.g., hard mask 405 and sacrificial SiGe layer 404; buried local interconnect placeholder 414; and, local interconnect placeholders 1, 2.

FIG. 4G is a block diagram of an example fabrication state 400G of a stacked FET with cross-coupling, in accordance with some embodiments of the present disclosure. The example fabrication state 400G can represent the cells 402-U, 402-L after operation 316. In comparison to the example fabrication state 400F, the views X, Y1, Y2, ww, ss, of the example fabrication state 400G do not include the sacrificial SiGe layer 404, hard mask 405, bottom buried local and interconnect placeholder 414. While the fabrication tool does remove the sacrificial material of the local interconnect placeholders 1, 2, for clarity of further discussion, their locations remain as indicated by these reference numbers.

Referring back to FIG. 3A, the operation 316 shows a flow to a placeholder A. The placeholder A does not represent an operation of the method, but serves to connect the operations described in FIG. 3A with the other operations of method 300, which are described in greater detail with respect to FIG. 3B.

FIG. 3B is a process flow chart of operations 318 through 334 of the method 300, in accordance with some embodiments of the present disclosure. For clarity, these operations are described with respect to FIGS. 4H through 4N.

The process flow chart of FIG. 3B shows a flow from placeholder A to operation 318. As stated previously, the placeholder A does not represent an operation of the method 300, but serves to connect the operations 302-316 described in FIG. 3A with operations 318-334 described below.

At operation 318, the stacked FET with cross-coupling fabrication manager 100 can direct the fabrication tool to perform replacement gate formation. Performing replacement gate formation includes forming high-k metal gates. High-k metal gates provide the conductive gate electrode for the transistors. The materials for the gate structure may differ based on the type of device under construction (e.g., N-type or P-type).

FIG. 4H is a block diagram of an example fabrication state 400H of stacked FET with cross-coupling, in accordance with some embodiments of the present disclosure. The example fabrication state 400H can result from operation 318.

In view X, the cells 402-L, 402-U include gates 426. The gates 426 occupy the spaces created through the removal of the sacrificial SiGe layer 404 and hard mask 405 in operation 316.

In view Y1, the cells 402-L, 402-U include gates 426. The gates 426 occupy the spaces created through the removal of the placeholders, e.g., the bottom buried local interconnect placeholder 414 and local interconnect placeholders 1, 2.

In view Y2, the cells 402-L, 402-U include gates 426. The gates 426 occupy the spaces created through the removal of the hard mask 405 and local interconnect placeholders 1, 2. For clarity, the reference numbers, “1,” and, “2,” are used to refer to the local interconnects 1, 2 formed by the gates 426.

In view ww, the cells 402-L, 402-U include gates 426. The gates 426 occupy the spaces created through the removal of the hard mask 405 and local interconnect placeholders 1, 2. Similarly, in view ss, the cells 402-L, 402-U include gates 426 that occupy the spaces created through the removal of the hard mask 405 and local interconnect placeholders 1, 2.

Referring back to FIG. 3B, at operation 320, the stacked FET with cross-coupling fabrication manager 100 can direct the fabrication tool to perform a late gate cut. Performing the late gate cut means removing gate material, BOX 403, ILD 408 to form late gate cut 425.

FIG. 4I is a block diagram of an example fabrication state 4001 of stacked FET with cross-coupling, in accordance with some embodiments of the present disclosure. The example fabrication state 4001 can result from operation 320. In comparison to example fabrication state 400H, the views X, Y1, ww, ss are unchanged. However, the view Y2 includes the late gate cut 425. Additionally, the upper right panel shows the late gate cut on both cells 402-L, 402-U.

Referring back to FIG. 3B, at operation 322, the stacked FET with cross-coupling fabrication manager 100 can direct the fabrication tool to form middle of line (MOL) contact trenches. Forming MOL contact trenches means removing gate material, BOX 403, ILD 408 to form trenches for the placement of contacts. Contacts can be electrically conductive structure that provides electrical contact between the GND, BL2, and the transistors of the stacked FET with cross-coupling.

At operation 324, the stacked FET with cross-coupling fabrication manager 100 can direct the fabrication tool to remove GND, or drain (Vdd), placeholder (e.g., GND placeholder 416) and BL2 placeholder 418. Removing the GND placeholder 416 and BL2 placeholder 418 provides the space to fabricate the GND and BL2.

At operation 326, the stacked FET with cross-coupling fabrication manager 100 can direct the fabrication tool to form MOL contacts. The MOL contacts can be electrically conductive structures that provide electrical contact between the GND, BL2, and transistors of the example cells 402-U, 402-L.

FIG. 4J is a block diagram of an example fabrication state 400J of stacked FET with cross-coupling, in accordance with some embodiments of the present disclosure. The example fabrication state 400J can result from operations 322, 324, 326. As shown in the upper right panel, the cell 402-U includes MOL contacts 427, 428, 430, 432. In contrast, the cell 402-L includes MOL contacts 427, 428. In view Y2, the example fabrication state 400J is unchanged from the example fabrication state 400I.

In view X, the cells 402-U, 402-L include MOL contacts 427, 428, 432. More specifically, the MOL contact 427 is for the GND. The MOL contact 428 is for BL2, and the MOL contact 432 is for BL1.

In view Y1, the cell 402-U includes MOL contacts 428, 430. The MOL contact 430 is for the local interconnect 2.

In view ww, the cell 400-U includes MOL contact 428. Further, in view ss, the cell 402-U include MOL contact 430.

Referring back to FIG. 3B, at operation 328, the stacked FET with cross-coupling fabrication manager 100 can direct the fabrication tool to form the BEOL and perform carrier wafer bonding.

FIG. 4K is a block diagram of an example fabrication state 400K of an example stacked FET with cross-coupling, in accordance with some embodiments of the present disclosure. The example fabrication state 400K results from operation 328. In views X, Y1, Y2, ww, ss, the cell 402-U includes backside contact 434 and carrier wafer 436.

At operation 330, the stacked FET with cross-coupling fabrication manager 100 can direct the fabrication tool to perform wafer flip and silicon (SI) substrate removal. Performing the wafer flip makes it possible for the fabrication tool to remove the Si substrate, e.g., substrate 401.

FIG. 4L is a block diagram of an example fabrication state 400L of the example stacked FET with cross-coupling, in accordance with some embodiments of the present disclosure. The example fabrication state 400L results from operation 330. In comparison to the example fabrication state 400K, the views X, Y1, Y2, ww, ss, do not include the substrate 401, which is removed at operation 330.

At operation 332, the stacked FET with cross-coupling fabrication manager 100 can direct the fabrication tool to form backside contacts.

FIG. 4M is a block diagram of an example fabrication state 400M of the example stacked FET with cross-coupling, in accordance with some embodiments of the present disclosure. The example fabrication state 400M results from operation 332. In comparison to the example fabrication state 400L, the views Y2, ww, ss, are unchanged. In view X, the cell 400-L includes backside contacts 438. In view Y1, the cell 400-L includes backside contact 440.

At operation 334, the stacked FET with cross-coupling fabrication manager 100 can direct the fabrication tool to form the backside power rail (BPR) and backside power distribution network (PDN).

FIG. 4N is a block diagram of an example fabrication state 400N of the example stacked FET with cross-coupling, in accordance with some embodiments of the present disclosure. The example fabrication state 400N results from operation 334.

In comparison to the example fabrication state 400M, the views X, Y1, Y2, ww, ss include backside ILD 444 and PDN 448. Further, the view X includes NTS 442, BPR 446, and backside PDN 448. The NTS 442 represents a contact between the backside contact 434 and backside PDN 448. The ILD 444 can be similar to the ILD 408. Additionally, the BPR 446 represents the source, e.g., Vss for power. Further, the backside PDN 448 represents the power supply.

In view Y1, the cell 400-L includes the ILD 444. In view Y2, the cell 402-L includes BPR(Vss) 446, and BPR (VDD) 450.

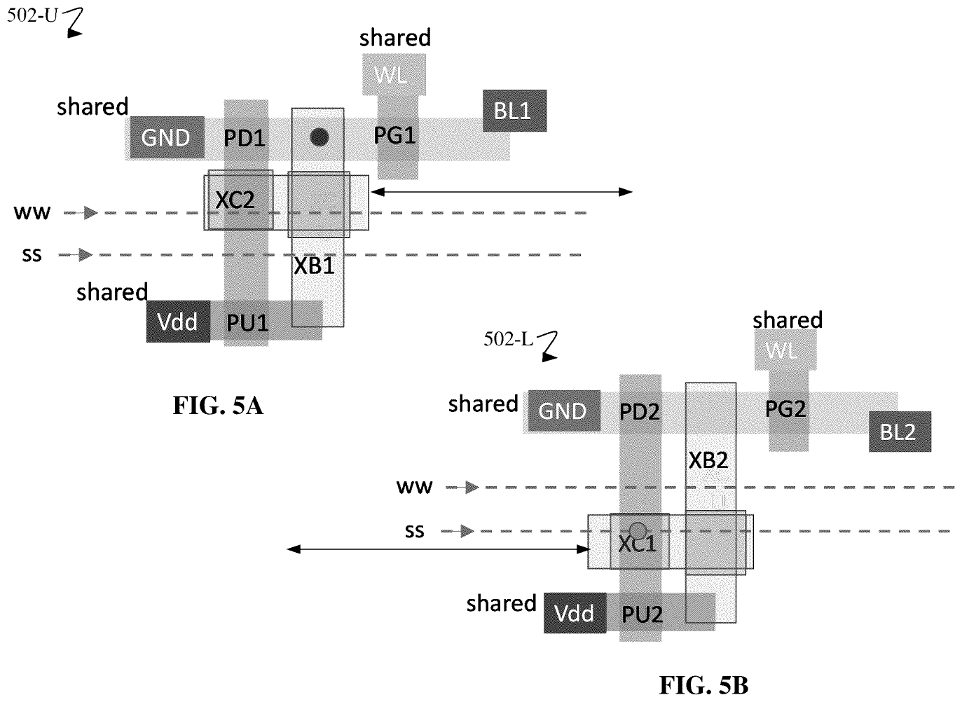

FIG. 5A is a top view of an upper level cell 502-U of the stacked FET with cross-coupling, in accordance with some embodiments of the present disclosure. The upper level cell 502-U can be similar to the cell 202-U, described with respect to FIG. 2B.

FIG. 5B is a top view of a lower level cell 500-L of the stacked FET with cross-coupling, in accordance with some embodiments of the present disclosure. The lower level cell 502-L can be similar to the cell 202-L, described with respect to FIG. 2C.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

A non-limiting list of examples are provided hereinafter to demonstrate some aspects of the present disclosure. Example 1 is a complementary metal oxide semiconductor (CMOS) device. The device includes a hybrid cross-couple contact, wherein the hybrid cross-couple contact comprises: a frontside contact to a gate of the CMOS device, wherein the frontside contact is disposed on a frontside of the CMOS device; and a source contact to a source of the CMOS device, wherein the source contact is disposed on a backside of the CMOS device; and a drain contact to a drain of the CMOS device, wherein the drain contact is disposed on a backside of the CMOS device.

Example 2 includes the device of example 1, including or excluding optional features. In this example, the hybrid cross-couple contact forms a node for a static random access memory (SRAM) device. Optionally, the SRAM device comprises a plurality of backside contacts that wire Vdd and Vss power supplies for the SRAM device from the backside of the CMOS device. Optionally, the SRAM device comprises an 8-way shared GND contact wiring to the backside of the CMOS device. Optionally, the SRAM device comprises a 4-way shared VDD contact wiring to the backside of the CMOS device. Optionally, the SRAM device comprises a 4-way shared word line contact wiring to the frontside of the CMOS device.

Example 3 is a complementary metal oxide semiconductor (CMOS) device. The device includes a hybrid cross-couple contact, wherein the hybrid cross-couple contact forms a node for a static random access memory (SRAM) device, and wherein the hybrid cross-couple contact comprises: a frontside contact to a gate of the CMOS device, wherein the frontside contact is disposed on a frontside of the CMOS device; and a source contact to a source of the CMOS device, wherein the source contact is disposed on a backside of the CMOS device; and a drain contact to a drain of the CMOS device, wherein the drain contact is disposed on a backside of the CMOS device.

Example 4 includes the device of example 3, including or excluding optional features. In this example, the SRAM device comprises a plurality of backside contacts that wire Vdd and Vss power supplies for SRAM from the backside of the CMOS device.

Example 5 includes the device of any one of examples 3 to 4, including or excluding optional features. In this example, the SRAM device comprises an 8-way shared GND contact wiring to the backside of the CMOS device.

Example 6 includes the device of any one of examples 3 to 5, including or excluding optional features. In this example, the SRAM device comprises a 4-way shared VDD contact wiring to the backside of the CMOS device.

Example 7 includes the device of any one of examples 3 to 6, including or excluding optional features. In this example, the SRAM device comprises a 4-way shared word line contact wiring to the frontside of the CMOS device.

Example 8 is a complementary metal oxide semiconductor (CMOS) device. The device includes a hybrid cross-couple contact, wherein the hybrid cross-couple contact forms a node for a static random access memory (SRAM) device, and wherein the SRAM device comprises a plurality of backside contacts that wire Vdd and Vss power supplies for SRAM from the backside of the CMOS device, and wherein the hybrid cross-couple contact comprises: a frontside contact to a gate of the CMOS device, wherein the frontside contact is disposed on a frontside of the CMOS device; and a source contact to a source of the CMOS device, wherein the source contact is disposed on a backside of the CMOS device; and a drain contact to a drain of the CMOS device, wherein the drain contact is disposed on a backside of the CMOS device.

Example 9 includes the device of example 8, including or excluding optional features. In this example, the SRAM device comprises an 8-way shared GND contact wiring to the backside of the CMOS device.

Example 10 includes the device of any one of examples 8 to 9, including or excluding optional features. In this example, the SRAM device comprises a 4-way shared VDD contact wiring to the backside of the CMOS device.

Example 11 includes the device of any one of examples 8 to 10, including or excluding optional features. In this example, the SRAM device comprises a 4-way shared word line contact wiring to the frontside of the CMOS device.

Example 12 is a complementary metal oxide semiconductor (CMOS) device. The device includes a hybrid cross-couple contact, wherein the hybrid cross-couple contact forms a node for a static random access memory (SRAM) device, and wherein the SRAM device comprises an 8-way shared GND contact wiring to the backside of the CMOS device, and wherein the hybrid cross-couple contact comprises: a frontside contact to a gate of the CMOS device, wherein the frontside contact is disposed on a frontside of the CMOS device; and a source contact to a source of the CMOS device, wherein the source contact is disposed on a backside of the CMOS device; and a drain contact to a drain of the CMOS device, wherein the drain contact is disposed on a backside of the CMOS device.

Example 13 includes the device of example 12, including or excluding optional features. In this example, the SRAM device comprises a plurality of backside contacts that wire Vdd and Vss power supplies for SRAM from the backside of the CMOS device.

Example 14 includes the device of any one of examples 12 to 13, including or excluding optional features. In this example, the SRAM device comprises a 4-way shared VDD contact wiring to the backside of the CMOS device.

Example 15 includes the device of any one of examples 12 to 14, including or excluding optional features. In this example, the SRAM device comprises a 4-way shared word line contact wiring to the frontside of the CMOS device.

Example 16 is a computer program product comprising program instructions stored on a computer readable storage medium. The computer-readable medium includes instructions that direct the processor to performing bottom dummy gate formation; performing source-drain (S/D) epitaxy formation; performing a first interlayer dielectric (ILD) formation; performing gate cut formation; performing bottom buried local interconnect placeholder formation; performing a second ILD formation; performing middle local interconnect placeholder formation; performing wafer bonding on a top channel of the wafer; performing top dummy gate formation; performing top S/D epitaxy formation; performing a first top ILD formation; performing a top gate cut formation; forming a replacement metal gate opening; performing dummy gate removal; performing release of a silicon-germanium (SiGe) sacrificial layer; performing a local interconnect placeholder removal; performing a replacement gate formation; performing a late gate cut; forming middle of line (MOL) contact trenches; removing a bit line 2 placeholder; removing a GND placeholder; removing a drain placeholder; forming a plurality of MOL contacts; forming back end of line (BEOL); performing carrier wafer bonding; performing wafer flip; performing substrate removal; forming a plurality of backside contacts; forming a backside power rail; and forming a backside power distribution network.

Example 17 includes the computer-readable medium of example 16, including or excluding optional features. In this example, the wafer comprises a hybrid cross-couple contact, and wherein the hybrid cross-couple contact forms a node for a static random access memory (SRAM) device. Optionally, the SRAM device comprises a plurality of backside contacts that wire Vdd and Vss power supplies for the SRAM device from a backside of the wafer. Optionally, the SRAM device comprises an 8-way shared GND contact wiring to a backside of the wafer. Optionally, the SRAM device comprises a 4-way shared VDD contact wiring to a backside of the wafer. Optionally, the SRAM device comprises a 4-way shared word line contact wiring to a frontside of the wafer.

What is claimed is:

1. A complementary metal oxide semiconductor (CMOS) device comprising:
a hybrid cross-couple contact, wherein the hybrid cross-couple contact comprises:
a frontside contact to a gate of the CMOS device, wherein the frontside contact is disposed on a frontside of the CMOS device; and
a source contact to a source of the CMOS device, wherein the source contact is disposed on a backside of the CMOS device; and
a drain contact to a drain of the CMOS device, wherein the drain contact is disposed on the backside of the CMOS device.

2. The CMOS device of claim 1, wherein the hybrid cross-couple contact forms a node for a static random access memory (SRAM) device.

3. The CMOS device of claim 2, wherein the SRAM device comprises a plurality of backside contacts that wire Vdd and Vss power supplies for the SRAM device from the backside of the CMOS device.

4. The CMOS device of claim 2, wherein the SRAM device comprises an 8-way shared GND contact wiring to the backside of the CMOS device.

5. The CMOS device of claim 2, wherein the SRAM device comprises a 4-way shared VDD contact wiring to the backside of the CMOS device.

6. The CMOS device of claim 2, wherein the SRAM device comprises a 4-way shared word line contact wiring to the frontside of the CMOS device.

7. A complementary metal oxide semiconductor (CMOS) device comprising:
a hybrid cross-couple contact, wherein the hybrid cross-couple contact forms a node for a static random access memory (SRAM) device, and wherein the hybrid cross-couple contact comprises:
a frontside contact to a gate of the CMOS device, wherein the frontside contact is disposed on a frontside of the CMOS device; and
a source contact to a source of the CMOS device, wherein the source contact is disposed on a backside of the CMOS device; and
a drain contact to a drain of the CMOS device, wherein the drain contact is disposed on the backside of the CMOS device.

8. The CMOS device of claim 7, wherein the SRAM device comprises a plurality of backside contacts that wire Vdd and Vss power supplies for SRAM from the backside of the CMOS device.

9. The CMOS device of claim 7, wherein the SRAM device comprises an 8-way shared GND contact wiring to the backside of the CMOS device.

10. The CMOS device of claim 7, wherein the SRAM device comprises a 4-way shared VDD contact wiring to the backside of the CMOS device.

11. The CMOS device of claim 7, wherein the SRAM device comprises a 4-way shared word line contact wiring to the frontside of the CMOS device.

12. A complementary metal oxide semiconductor (CMOS) device comprising:
a hybrid cross-couple contact, wherein the hybrid cross-couple contact forms a node for a static random access memory (SRAM) device, and wherein the SRAM device comprises a plurality of backside contacts that wire Vdd and Vss power supplies for SRAM from a backside of the CMOS device, and wherein the hybrid cross-couple contact comprises:
a frontside contact to a gate of the CMOS device, wherein the frontside contact is disposed on a frontside of the CMOS device; and
a source contact to a source of the CMOS device, wherein the source contact is disposed on the backside of the CMOS device; and
a drain contact to a drain of the CMOS device, wherein the drain contact is disposed on the backside of the CMOS device.

13. The CMOS device of claim 12, wherein the SRAM device comprises an 8-way shared GND contact wiring to the backside of the CMOS device.

14. The CMOS device of claim 12, wherein the SRAM device comprises a 4-way shared VDD contact wiring to the backside of the CMOS device.

15. The CMOS device of claim 12, wherein the SRAM device comprises a 4-way shared word line contact wiring to the frontside of the CMOS device.

16. A complementary metal oxide semiconductor (CMOS) device comprising:
a hybrid cross-couple contact, wherein the hybrid cross-couple contact forms a node for a static random access memory (SRAM) device, and wherein the SRAM device comprises an 8-way shared GND contact wiring to a backside of the CMOS device, and wherein the hybrid cross-couple contact comprises:
a frontside contact to a gate of the CMOS device, wherein the frontside contact is disposed on a frontside of the CMOS device; and
a source contact to a source of the CMOS device, wherein the source contact is disposed on the backside of the CMOS device; and
a drain contact to a drain of the CMOS device, wherein the drain contact is disposed on the backside of the CMOS device.

17. The CMOS device of claim 16 wherein the SRAM device comprises a plurality of backside contacts that wire Vdd and Vss power supplies for SRAM from the backside of the CMOS device.

18. The CMOS device of claim 16, wherein the SRAM device comprises a 4-way shared VDD contact wiring to the backside of the CMOS device.

19. The CMOS device of claim 16, wherein the SRAM device comprises a 4-way shared word line contact wiring to the frontside of the CMOS device.

20. A computer program product comprising program instructions stored on a computer readable storage medium, the program instructions executable by a processor to cause the processor to perform a method on a wafer, the method comprising:
performing bottom dummy gate formation;
performing source-drain (S/D) epitaxy formation;
performing a first interlayer dielectric (ILD) formation;
performing gate cut formation;
performing bottom buried local interconnect placeholder formation;
performing a second ILD formation;
performing middle local interconnect placeholder formation;
performing wafer bonding on a top channel of the wafer;
performing top dummy gate formation;
performing top S/D epitaxy formation;
performing a first top ILD formation;
performing a top gate cut formation;
forming a replacement metal gate opening;
performing dummy gate removal;
performing release of a silicon-germanium (SiGe) sacrificial layer;
performing a local interconnect placeholder removal;
performing a replacement gate formation;
performing a late gate cut;
forming middle of line (MOL) contact trenches;
removing a bit line 2 placeholder;
removing a GND placeholder;
removing a drain placeholder;
forming a plurality of MOL contacts;
forming back end of line (BEOL);
performing carrier wafer bonding;
performing wafer flip;
performing substrate removal;
forming a plurality of backside contacts;
forming a backside power rail; and
forming a backside power distribution network.

21. The computer program product of claim 20, wherein the wafer comprises a hybrid cross-couple contact, and wherein the hybrid cross-couple contact forms a node for a static random access memory (SRAM) device.

22. The computer program product of claim 21, wherein the SRAM device comprises a plurality of backside contacts that wire Vdd and Vss power supplies for the SRAM device from a backside of the wafer.

23. The computer program product of claim 21, wherein the SRAM device comprises an 8-way shared GND contact wiring to a backside of the wafer.

24. The computer program product of claim 21, wherein the SRAM device comprises a 4-way shared VDD contact wiring to a backside of the wafer.

25. The computer program product of claim 21, wherein the SRAM device comprises a 4-way shared word line contact wiring to a frontside of the wafer.
